(19) United States
(12) Patent Application Publication
(10) Pub. No.: US 2012/0138998 A1
(43) Pub. Date: Jun. 7, 2012

(54) Light-Emitting Device

(75) Inventors: Hiroki ITOU, Higashiomi-shi (JP); Daisuke SAKUMOTO, Higashiomi-shi (JP)

(73) Assignee: KYOCERA CORPORATION, Kyoto-shi, Kyoto (JP)

(21) Appl. No.: 13/388,439

(22) PCT Filed: Aug. 27, 2010
(86) PCT No.: PCT/JP2010/064553

§ 371 Date: Feb. 1, 2012

(30) Foreign Application Priority Data
Aug. 27, 2009 (JP) 2009-197139

(51) Int. Cl. H01L 33/50

(52) U.S. Cl. 257/98; 257/E33.071

(57) ABSTRACT

A light-emitting device (1) includes a substrate, a light-emitting element mounted on the substrate, a frame disposed on the substrate so as to surround the light-emitting element, and a wavelength converter supported on the frame so as to be opposed at an interval from the light-emitting element. In the light-emitting device, the wavelength converter has a thickness becoming smaller from an edge toward a center of the wavelength converter.

### TECHNICAL FIELD

The present invention relates to a light-emitting device including a light-emitting element.

### BACKGROUND ART

In recent years, developments directed toward producing light-emitting devices which are of the type having a light source including a light-emitting element have been under way. Such a light-emitting device with a light-emitting element is noteworthy for its feature as to power consumption or product lifetime. For example, in the field of residential luminaire technology, the light-emitting device with a light-emitting element is required to possess the capability of emitting light portions of a plurality of color temperatures in a selective manner.

By way of example, there is a light-emitting device designed to convert light emitted from a light-emitting element into light lying in a specific band of wavelengths by means of a wavelength converter, and produce output of the light (refer to Japanese Unexamined Patent Publication JP-A 2004-343149, for example).

There has been an increasing demand for further improvement in the light-emitting device in terms of light output uniformity. That is, the light-emitting device needs to be so contrived that, when viewed in a plan view, its midportion and periphery are made uniform in light output capability.

### SUMMARY OF INVENTION

A photoelectric conversion device in accordance with one embodiment of the invention includes: a substrate; a light-emitting element mounted on the substrate; a frame disposed on the substrate so as to surround the light-emitting element; and a wavelength converter supported on the frame so as to be opposed at an interval from the light-emitting element. Moreover, in the photoelectric conversion device, wherein the wavelength converter has a thickness becoming smaller from an edge toward a center of the wavelength converter.

### BRIEF DESCRIPTION OF DRAWINGS

FIG. 1 is a sectioned perspective view showing a schematic overview of a light-emitting device according to an embodiment;

FIG. 2 is a sectional view of a light-emitting device according to the embodiment;

FIG. 3 is a sectional view showing a condition of travel of light from the light-emitting device as shown in FIG. 2;

FIG. 4 is a sectional view of an example of modified forms of the light-emitting device; and

FIG. 5 is a sectional view of an example of modified forms of the light-emitting device.

### DESCRIPTION OF EMBODIMENTS

Hereinafter, an embodiment of a light-emitting device pursuant to the invention will be described with reference to the accompanying drawings. It should be noted that the invention is not limited to the embodiment as set forth hereinbelow.

<General Structure of Photoelectric Device>

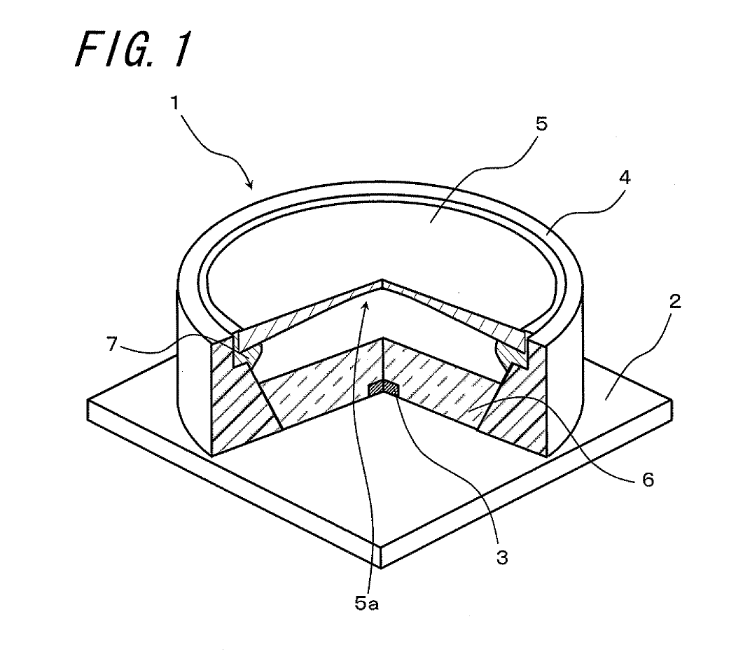

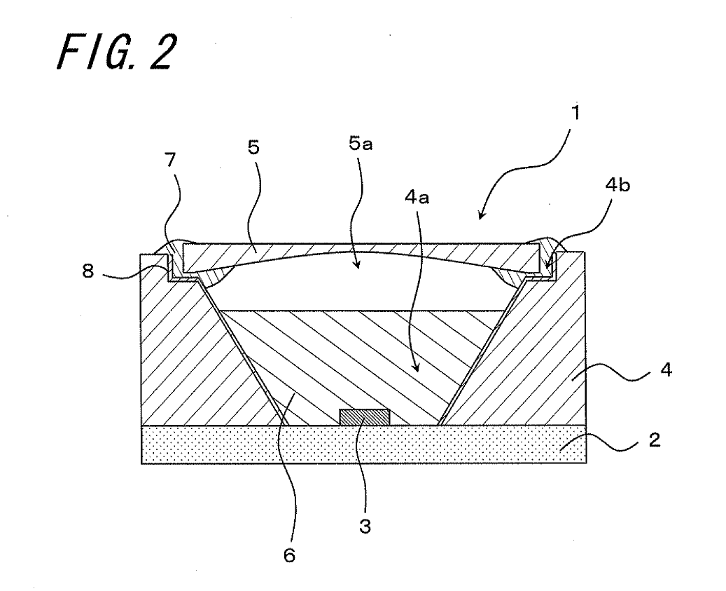

FIG. 1 is a schematic perspective view, partly in section, of a light-emitting device 1 according to an the embodiment. Moreover, FIG. 2 is a sectional view of the light-emitting device shown in FIG. 1.

The light-emitting device 1 according to the embodiment includes: a substrate 2; a light-emitting element 3 mounted on the substrate 2; a frame 4 disposed on the substrate 2 so as to surround the light-emitting element 3; and a wavelength converter 5 supported on the frame 4 so as to be opposed at an interval from the light-emitting element 3. For example, the light-emitting element 3 is a light emitting diode for emitting light to the outside by exploiting electron-positive hole reunion in semiconductor-based p-n junction.

The substrate 2 is an insulating substrate made of a ceramic material such as alumina or mullite, a glass ceramic material or the like, or a composite material obtained by mixing two or more of those materials. Also, polymeric resin containing metal oxide fine particles in a dispersed state may be used for the substrate 2.

The substrate 2 is formed with a wiring conductor for permitting electrical conduction between the interior of the substrate 2 and the exterior thereof. The wiring conductor is made of an electrically conductive material such as tungsten, molybdenum, manganese, copper, or the like. For example, the wiring conductor can be obtained by a method including a step of preparing a metal paste by adding an organic solvent to powder of tungsten or the like, a step of printing the metal paste in a predetermined pattern onto ceramic green sheets constituting the substrate 2, a step of laminating a plurality of the ceramic green sheets on top of each other, and a step of firing the resultant. Note that the surface of the wiring conductor exposed internally or externally of the substrate 2 is clad with a plating layer made of nickel, gold, or the like for protection against oxidation.

Moreover, in the interest of efficient reflection of light above the substrate 2, an upper face of the substrate 2 is formed with a metallic reflection layer made of aluminum, silver, gold, copper, platinum, or the like at an interval from the wiring conductor and the plating layer. Instead of the metallic reflection layer, an insulating transparent member such as white ceramic powder-containing silicone resin can be applied to the upper face of the substrate 2, excluding an area bearing the light-emitting element. In this way, light emitted from the light-emitting element 3 is reflected diffusively from the top of the substrate 2, and is allowed to enter the wavelength converter 5 without converging to a part of the wavelength converter 5. As a result, the light emitted from the light-emitting element 3 is less likely to converge to a specific location of the wavelength converter 5, wherefore a decline in conversion efficiency in the specific location of the wavelength converter 5, or a decline in transmittance caused by a temperature rise in the specific location of the wavelength converter 5, can be suppressed effectively.

The light-emitting element 3 is mounted on the substrate 2. More specifically, the light-emitting element 3 is placed, for electrical connection, on the plating layer adhered to the surface of the wiring conductor formed on the substrate 2 via, for example, a brazing material or solder.

For example, an element for giving off excitation light of a wavelength region in a range of 370 nm or more and 420 nm or less can be used for the light-emitting element 3. Note that there is no particular limitation to the light-emitting element 3 so long as it is capable of giving off light ranging from 370 nm to 420 nm in terms of center wavelength.

In this construction, the light-emitting element substrate of the light-emitting element 3 has, on its surface, a light emitting layer made of a semiconductor material. For example, a semiconductor such as zinc selenide or gallium nitride can be used as the semiconductor material. The light emitting layer can be formed by means of metalorganic chemical vapor deposition, crystal growth method such as molecular beam epitaxy, or otherwise.

The frame 4, which is made of a ceramic material that is identical in composition with the substrate 2, is placed on the upper face of the substrate 2, so that it is fired with the substrate 2 in a unified manner. Alternatively, the frame 4 may be formed independently of the substrate 2. In this case, the frame 4 is configured to have a reflection surface at its inner wall. The frame 4, being a separate component, is bonded onto the substrate 2 via a transparent adhesive such as silicone resin.

In the case of forming the adhesive from a transparent material, light which has been transmitted directly to the adhesive from the light-emitting element 3, as well as light which has been emitted into the light-emitting device 1 from the wavelength converter 5 and transmitted to the adhesive, enters the adhesive. The light having entered the adhesive undergoes repetitive light reflection at the bonding surfaces of the substrate 1 and the frame 4, and part of the light is emitted into the light-emitting device 1. After that, the light portions act to excite the fluorescent substances within the wavelength converter 5, or are radiated out of the light-emitting device 1 after passing through the wavelength converter 5. If the adhesive is not transparent, the light which has been transmitted directly to the adhesive from the light-emitting element 3, as well as the light which has been emitted into the light-emitting device 1 from the wavelength converter 5 and transmitted to the adhesive, is likely to be absorbed into the adhesive, with the consequent increase of optical losses in the light-emitting device 1. In contrast, where the adhesive is transparent, part of light having entered the adhesive is emitted into the light-emitting device 1 and can thus be utilized as output light from the light-emitting device 1. In consequence, by bonding the frame 4 onto the substrate 2 via the transparent adhesive such as silicone resin, it is possible to lessen optical losses due to light absorption by the adhesive, and thereby enhance the light output capability of the light-emitting device.

The frame 4 is so disposed as to surround the light-emitting element 3 mounted on the substrate 2. The interior of the frame 4 is formed with a circular or rectangular through hole 4a for housing the light-emitting element 3. In the case where the through hole 4a of the frame 4 is circular in shape, the light emitted from the light-emitting element 3 can be reflected evenly in all directions and is thus caused to radiate outward with a very high degree of uniformity.

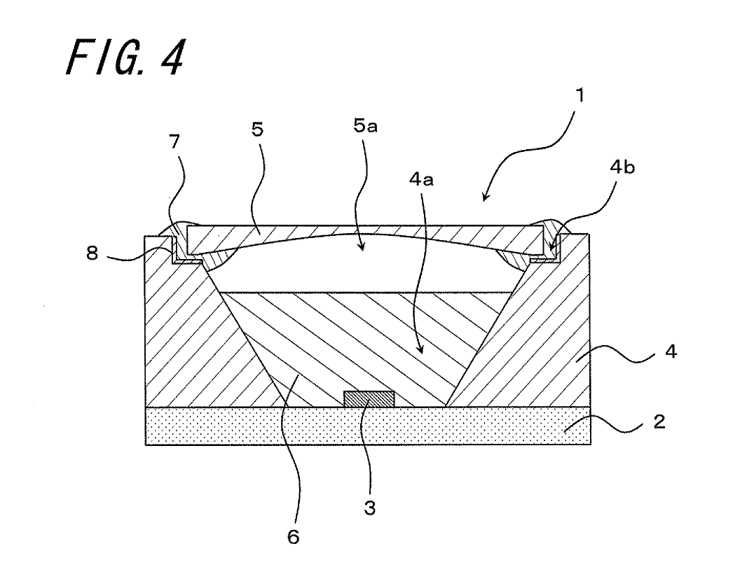

Moreover, when viewed in a cross-sectional view, the frame 4 is so shaped that its inner wall extends at a gradual widthwise incline from a lower portion to an upper portion thereof. Further, an upper end of the frame 4 is internally stepped to provide a shoulder 4b. An inclined inner wall of the frame 4 is formed with a metallic layer made for example of tungsten, molybdenum, copper, or silver, and a metallic plating layer 8 made of nickel, gold, or the like for covering the metallic layer. The metallic plating layer 8 has the capability of reflective dispersion of the light emitted from the light-emitting element 3. Alternatively, as shown in FIG. 4, in the case where the frame 4 is made of a ceramic material and the metallic plating layer 8 is not formed on the inner wall of the frame 4, it is advisable that the inner wall of the frame 4 is configured to have, a ceramic material-made reflection surface in an exposed state. This enables reflective dispersion of the light emitted from the light-emitting element 3. As a result, the light which has been emitted from the light-emitting element 3 and thence reflectively dispersed by the frame 4 is allowed to enter the wavelength converter 5 while being restrained from converging to a specific location of the wavelength converter 5. That is, the light emitted from the light-emitting element 3 is less likely to converge to a specific location of the wavelength converter 5. This makes it possible to suppress effectively a decline in conversion efficiency in the specific location of the wavelength converter 5 or a decline in transmittance caused by a temperature rise in the specific location of the wavelength converter 5.

Moreover, the angle of inclination of the inner wall of the frame 4 is set to fall, for example, in a range of 55° or more and 70° or less with respect to the upper face of the substrate 2. Further, a surface roughness of the metallic plating layer 8 is set to fall, for example, in a range of 1 μm or more and 3 μm or less in terms of arithmetic mean height Ra.

The shoulder 4b of the frame 4 is provided for the sake of supporting the wavelength converter 5. The shoulder 4b is formed by cutting part of the top of the frame 4 inwardly, so that it is able to support the edge of the wavelength converter 5. Note that the metallic plating layer 8 extends over the surface of the shoulder 4b. By virtue of the interposition of the metallic plating layer 8 between the frame 4 and the wavelength converter 5, heat generated in the wavelength converter 5 can be dissipated from the wavelength converter 5 to the frame 4 through a resin 7 and the metallic plating layer 8. This makes it possible to protect the wavelength converter 5 from a temperature rise effectively.

In the light-emitting device as shown in FIG. 4, the metallic plating layer 8 is formed on the inner wall of the shoulder 4b, and the metallic plating layer 8 is contacted by the resin 7. On the other hand, the metallic plating layer 8 is not formed on a surface of the inner wall of the frame 4 other than the shoulder-bearing surface. In this way, heat transferred to the resin 7 from the wavelength converter 5 can be readily transmitted to the frame 4 through the metallic plating layer 8 formed on the shoulder 4b. Accordingly, in contrast to the case where the metallic plating layer 8 is formed on the entire surface of the inner wall of the frame 4, heat is less likely to be conducted through the region surrounded by the frame 4. This makes it possible to suppress a decline in the transmittance of a sealing resin 6 caused by heat, as well as to facilitate dissipation of heat from the frame 4 to the exterior thereof.

Moreover, the metallic plating layer 8 formed on the shoulder 4b is covered with the resin 7. By covering the metallic plating layer 8 with the resin 7, the heat transferred to the resin 7 from the wavelength converter 5 can be transmitted efficiently to the frame 4.

The sealing resin 6 is disposed in the region surrounded by the frame 4. The sealing resin 6 has the capabilities of sealing the light-emitting element 3 and permitting transmission of the light emitted from the light-emitting element 3 therethrough. Under the condition where the light-emitting element 3 is housed inside the frame 4, the sealing resin 6 is charged into the region surrounded by the frame 4 so that it is maintained at a level lower than the position of the shoulder 4b. Note that transparent insulating resin such for example as silicone resin, acrylic resin, or epoxy resin is used as the sealing resin 6.

The sealing resin 6 is disposed in the region surrounded by the frame 4 so as to cover the light-emitting element 3. At this time, a gap is created between the sealing resin 6 and the wavelength converter 5. In the presence of gas in the gap, there is a difference in refractive index between the sealing resin 6 and the gas. Due to the difference, a change in the direction of light travel or reflection of light may occur at the interface between the sealing resin 6 and the gas. Therefore, of the light traveling from the sealing resin 6 toward the wavelength converter 5, part of a first light portion, which is reflected from the wavelength converter 5 toward the sealing resin 6, is reflected at the interface between the gas and the sealing resin 6, and that part becomes a second light portion which travels toward the wavelength converter 5 once again. At this time, the traveling direction of the second light portion includes directions different from the direction in which the first light portion travels from the wavelength converter 5 toward the sealing resin 6. This helps lessen the occurrence of convergence of light to a specific location of the wavelength converter 5.

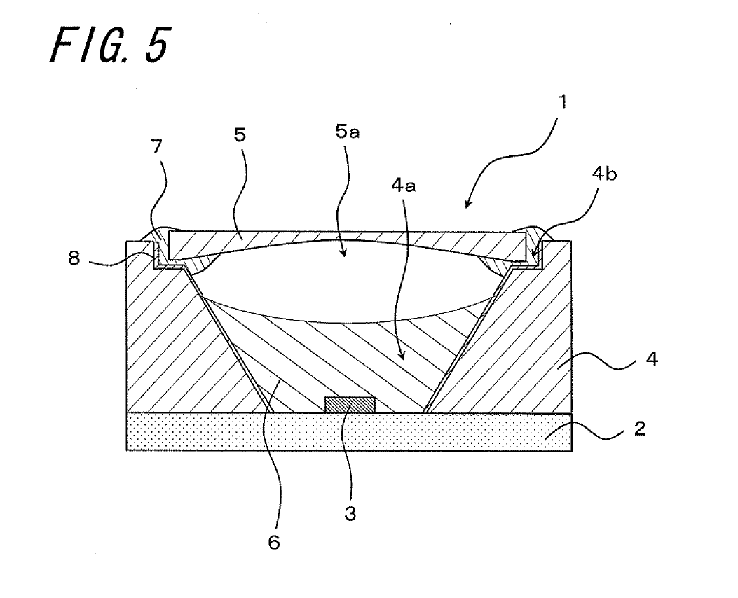

Moreover, as shown in FIG. 5, the upper face of the sealing resin 6 is curved downwardly from its edge situated at the inner wall of the frame 4 toward its center to provide a concave surface. The distance between the upper face of the edge of the sealing resin 6 and the lower face of the wavelength converter 5 located immediately above that upper face is set to be narrower than the distance between the upper face of the center of the sealing resin 6 and the lower face of the wavelength converter 5 located immediately above that center. By imparting a concavely curved profile to the upper face of the sealing resin 6, it is possible to facilitate reflection of light traveling from the wavelength converter 5 toward the sealing resin 6 at the upper face of the sealing resin 6, and thereby lessen the occurrence of convergence of light to a specific location of the wavelength converter 5 and also enhance the efficiency of light acquisition.

In the wavelength converter 5, upon the entrance of the light emitted from the light-emitting element 3, fluorescent substances contained therein are excited for emission of wavelength-converted light. The wavelength converter 5 is made of silicone resin, acrylic resin, epoxy resin, or the like that contains a blue phosphor for giving forth fluorescence in a range of 430 nm or more and 490 nm or less for example, a green phosphor for giving forth fluorescence in a range of 500 nm or more and 560 nm or less for example, a yellow phosphor for giving forth fluorescence in a range of 540 nm or more and 600 nm or less for example, and a red phosphor for giving forth fluorescence in a range of 590 nm or more and 700 nm or less for example. Note that the phosphors are dispersed evenly in the wavelength converter 5.

The wavelength converter 5 is supported on the frame 4 so as to be opposed at an interval from the light-emitting element 3. The wavelength converter 5 has a thickness becoming smaller from an edge toward a center of the wavelength converter 5. The wavelength converter 5 is disposed, with its center situated immediately above the light-emitting element 3.

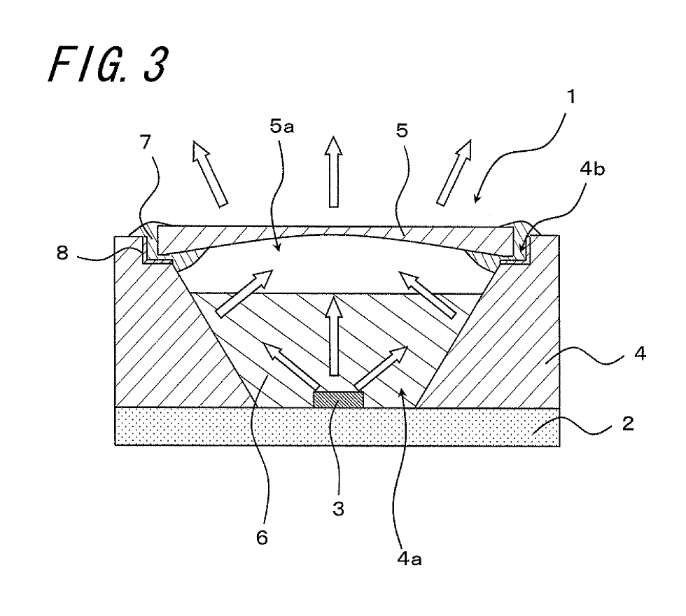

FIG. 3 is a sectional view of the light-emitting device, illustrating light which is being emitted from the light-emitting element. Arrows depicted in FIG. 3 indicate directions of travel of many light portions. The light-emitting element 3 is placed in a region overlapping the center of the lower face of the wavelength converter 5.

As shown in FIG. 3, the light emitted from the light-emitting element 3 tends to be reflected from the inner wall of the frame 4 so as to converge to the center of the wavelength converter 5. With this in view, the thickness of the center of the wavelength converter 5 subjected to convergence of the light emitted from the light-emitting element 3 is reduced for adjustment to the quantity of light which is excited by the light emitted from the light-emitting element 3.

That is, the light emitted from the light-emitting element 3 is, when reaching the wavelength converter 5, likely to converge to the center of the wavelength converter 5 rather than the edge of the wavelength converter 5. Therefore, if the wavelength converter 5 has a uniform thickness throughout its entirety, the center of the wavelength converter 5 will emit, following the completion of conversion, more light than does the edge of the wavelength converter 5. In this case, since many of the light portions excited within the wavelength converter 5 are emitted from the center of the wavelength converter 5, it follows that luminance varies significantly between the center and the edge in the wavelength converter 5 when viewed in a plan view. On the other hand, in the light-emitting device 1 according to the embodiment, the wavelength converter 5 has the thickness becoming smaller from the edge toward the center of the wavelength converter S. This makes it possible to reduce the quantity of light which is excited at the center of the wavelength converter 5 by the light emitted from the light-emitting element 3, and thereby suppress the variation of luminance between the center and the edge in the wavelength converter 5 when viewed in a plan view.

The wavelength converter 5 is formed with a concave 5a at its lower face opposed to the light-emitting element 3. The light emitted from the light-emitting element 3 tends to be reflected from the inner wall of the frame 4 so as to converge to the center of the wavelength converter 5. Therefore, by forming the concave 5a at the lower face of the wavelength converter 5, it is possible to obtain the effect of enveloping light traveling toward the wavelength converter 5 for the reduction of the quantity of light reflected from the lower face of the wavelength converter 5, and thereby achieve enhancement in external quantum efficiency. The concave 5a has the shape of a semi-sphere whose center coincides with the center of the wavelength converter 5 located above the light-emitting element 3. With the formation of the concave 5a in the wavelength converter 5, the lower face of the wavelength converter 5 can be inclined with respect to the upper face of the light-emitting element 3. In this case, the light coming from the light-emitting element 3 is less likely to be reflected from the lower face of the wavelength converter 5, wherefore the light coming from the light-emitting element 3 is allowed to enter the wavelength converter 5 with a high degree of efficiency.

Meanwhile, if the concave 5a is formed on the upper face of the wavelength converter 5 instead of the lower face thereof, in contrast to the case of forming the concave 5a on the lower face of wavelength converter 5, the light coming from the light-emitting element 3 is prone to being reflected from the lower face of the wavelength converter 5. This leads to a decrease in the effect of enhancing the wavelength conversion efficiency.

Moreover, the edge of the wavelength converter 5 is situated on the shoulder of the frame 4, and thus the wavelength converter 5 is surrounded, at its periphery, by the frame 4. Therefore, the light which has been emitted from the light-emitting element 3 and has entered the wavelength converter 5 may possibly reach the edge in the interior of the wavelength converter 5. In this case, by causing the light, now traveling from the edge of the wavelength converter 5 toward the frame 4, to reflect from the frame 4, the reflected light can be returned into the wavelength converter 5 once again. As a result, the light which has returned into the wavelength converter 5 can be excited by the fluorescent substances, with the consequent enhancement of the light output capability of the light-emitting device 1.

Moreover, the edge of the wavelength converter 5 has a uniform thickness. In this regard, the language “uniform thickness” is construed as encompassing thickness deviation of 0.5 μm or less. By configuring the edge of the wavelength converter 5 to have a uniform thickness, it is possible to effect adjustment so that light can be excited in a uniform light quantity throughout the perimeter of the wavelength converter 5, and thereby suppress unevenness in luminance along the perimeter of the wavelength converter 5.

In this construction, the thickness of the edge of the wavelength converter 5 is set to fall, for example, in a range of 0.7 mm or more and 3 mm or less. Moreover, the thickness of the concave 5a-bearing part of the wavelength converter 5 is set to fall, for example, in a range of 0.3 mm or more and 2.6 mm or less. Further, the difference in thickness between the edge of the wavelength converter 5 and the concave 5a-bearing part of the wavelength converter 5 is set to fall, for example, in a range of 0.4 mm or more and 2.7 mm or less. This thickness difference corresponds to the extent of the gradual change in thickness of the wavelength converter from the edge to the center thereof. Thus, the rate of thickness change in that part of the wavelength converter 5 situated on the shoulder 4b of the frame 4 is set to be smaller than the rate of thickness change in the concave 5a-bearing part of the wavelength converter 5.

When viewed in a plan view, the edge of the concave 5a of the wavelength converter 5 is positioned on the shoulder 4b of the frame 4. The wavelength converter 5 is fixed, at its edge, onto the shoulder 4b of the frame 4 via the resin 7. The resin 7 extends from the edge of the wavelength converter 5 to the position of the edge of the concave 5a of the wavelength converter 5. Note that transparent insulating resin such for example as silicone resin, acrylic resin, or epoxy resin is used as the resin 7.

In the range of the lower face of the wavelength converter 5, a coating of the resin 7 extends from the edge of the wavelength converter 5 to the concave 5a of the wavelength converter 5. This makes it possible to increase the area of the coating of the resin 7, and thereby connect the frame 4 with the wavelength converter 5 firmly. As a result, the strength of connection between the frame 4 and the wavelength converter 5 can be increased, wherefore the wavelength converter 5 can be protected against distortion. In addition, a change of the optical distance between the light-emitting element 3 and the wavelength converter 5 can be suppressed effectively.

According to the embodiment, the thickness of the wavelength converter 5 situated above the light-emitting element 3 becomes smaller from the edge toward the center of the wavelength converter 5. This makes it possible to effect adjustment so that the amount of excitation of the fluorescent substances within the wavelength converter 5 by the light emitted from the light-emitting element 3 can be rendered uniform throughout the entire surface of the wavelength converter 5 when viewed in a plan view. As a result, there is provided the light-emitting device 1 capable of enhancing the uniformity of light acquired from the wavelength converter 5.

It should be understood that the application of the invention is not limited to the specific embodiment described heretofore, and that many modifications and variations of the invention are possible within the scope of the invention.

<Method of Manufacturing Light-Emitting Device>

Now, a description will be given below as to a manufacturing method for the light-emitting device as shown in FIG. 1 or FIG. 2.

To begin with, the substrate 2 and the frame 4 are prepared. For example, in the case of forming the substrate 2 and the frame 4 from aluminum oxide sintered compact, an organic binder, a plasticizer or a solvent, and so forth are admixed in raw material powder such as aluminum oxide, silicon oxide, magnesium oxide, calcium oxide, and the like to obtain a mixture.

Subsequently, the mixture is charged into mold forms for the substrate 2 and the frame 4. Following the completion of drying process, unsintered molded products of the substrate 2 and the frame 4 are taken out.

Moreover, powder of high-melting-point metal such as tungsten, molybdenum, or the like is prepared for use. An organic binder, a plasticizer or a solvent, and so forth are admixed in the powder to obtain a metal paste. The metal paste is printed in a predetermined pattern onto ceramic green sheets constituting the substrate 2 taken out previously, and a plurality of the ceramic green sheets are laminated on top of each other. Then, ceramic green sheets constituting the frame 4 are bonded onto the laminated ceramic green sheets constituting the substrate 2, and they are fired in a unified manner under pressure.

Next, the surface of the wiring conductor exposed internally or externally of the substrate 2 is coated with a plating layer for protection of the wiring conductor against oxidation. Then, the light-emitting element 3 is placed on the plating layer for electrical connection via solder.

Moreover, for example, silicone resin is charged into the region surrounded by the frame 4. The silicone resin is cured to thereby form the sealing resin G.

Next, the wavelength converter 5 is prepared. The wavelength converter 5 can be formed by mixing fluorescent substances in resin in an uncured state, and shaping the mixture by means of a sheet molding technique such for example as the doctor blade method, the die coater method, the extrusion method, the spin coating method, or the dipping method. For example, the wavelength converter 5 can be obtained by charging the uncured material for the wavelength converter 5 into a mold form, and taking it out of the mold form following the completion of curing process.

Lastly, the thereby prepared wavelength converter 5 is bonded onto the shoulder 4b of the frame 4 via resin. In this way, the light-emitting device 1 can be manufactured.

1. A light-emitting device, comprising:
a substrate;
a light-emitting element mounted on the substrate;
a frame disposed on the substrate so as to surround the light-emitting element; and
a wavelength converter supported on the frame so as to be opposed at an interval from the light-emitting element,
wherein the wavelength converter has a thickness becoming smaller from an edge toward a center of the wavelength converter.

2. The light-emitting device according to claim 1,
wherein the wavelength converter is disposed, with the center of the wavelength converter situated immediately above the light-emitting element.

3. The light-emitting device according to claim 1,
wherein the wavelength converter is formed with a concave at its lower face opposed to the light-emitting element.

4. The light-emitting device according to claim 3,
wherein, when viewed in a cross-sectional view, a region surrounded by the frame is so shaped that its width becomes larger from a lower portion to an upper portion thereof, and
an upper end of the frame is internally stepped to provide a shoulder, and an edge of the concave is positioned on the shoulder when viewed in a plan view.

5. The light-emitting device according to claim 4,
wherein the shoulder of the frame and the edge of the wavelength converter are fixed to each other via a resin which extends over the concave of the wavelength converter.

6. The light-emitting device according to claim 1,
wherein a sealing resin is disposed in the region surrounded by the frame so as to cover the light-emitting element, and
a gap is provided between the sealing resin and the wavelength converter.

7. The light-emitting device according to claim 1,
wherein the light-emitting element is placed in a region overlapping a center of the lower face of the wavelength converter.

8. The light-emitting device according to claim 5,
wherein the shoulder has a metallic plating layer formed on its inner wall, and the metallic plating layer and the resin are kept in contact with each other.

9. The light-emitting device according to claim 8,
wherein the metallic plating layer is covered with the resin.
